(19) United States
(12) Patent Application Publication
(10) Pub. No.: US 2025/0385210 A1
(43) Pub. Date: Dec. 18, 2025

(54) PACKAGE STRUCTURE AND MANUFACTURING METHOD THEREOF

(71) Applicant: Powertech Technology Inc., Hsinchu County (TW)

(72) Inventor: Shang-Yu Chang Chien, Hsinchu County (TW)

(73) Assignee: Powertech Technology Inc., Hsinchu County (TW)

(21) Appl. No.: 19/047,485

(22) Filed: Feb. 6, 2025

(30) Foreign Application Priority Data
Jun. 13, 2024 (TW) 113121951

(51) Int. Cl. H01L 23/00; H01L 23/31; H01L 23/48; H01L 25/00; H01L 25/11

(52) U.S. Cl. CPC H01L 24/24; H01L 23/481; H01L 24/25; H01L 25/112; H01L 25/50; H01L 23/3185; H01L 2224/24101; H01L 2224/24105; H01L 2224/24146; H01L 2224/24147; H01L 2224/244; H01L 2224/2518

(57) ABSTRACT

A package structure including a first chip, a second chip, a plurality of fourth chips, a first redistribution layer, a second redistribution layer, a third redistribution layer, a first dielectric body, a second dielectric body, and a conductive member is provided. The first chip is disposed between the first redistribution layer and the third redistribution layer. The conductive member is disposed between the first redistribution layer and the second redistribution layer. The second redistribution layer is electrically connected to the first chip through the conductive member and the first redistribution layer. The second redistribution layer is disposed between the second chip and the fourth chip. Two of the fourth chips are electrically connected to each other through the second redistribution layer and the second chip. The first dielectric body covers the first chip, the second chip, the first redistribution layer, the second redistribution layer, the third redistribution layer, and the conductive member. The second dielectric body covers the second redistribution layer.

### CROSS-REFERENCE TO RELATED APPLICATION

This application claims the priority benefit of Taiwan application serial no. 113121951, filed on Jun. 13, 2024. The entirety of the above-mentioned patent application is hereby incorporated by reference herein and made a part of this specification.

### BACKGROUND

### Technical Field

The disclosure relates to a package structure and a manufacturing method thereof, and more particularly, to a package structure integrating a plurality of heterogeneous chips and a manufacturing method thereof.

### Description of Related Art

With the advancement of science and technology, electronic products have also become more diversified in line with market demand. In order to meet diverse requirements of the electronic products, it is often necessary to integrate a plurality of chips into a single package structure. For the package structure with a plurality of chips, how to make it smaller in size but still have better quality or performance is actually a research topic.

### SUMMARY

The disclosure provides a package structure and a manufacturing method thereof, and the package structure may have a smaller size and better quality or performance.

A package structure in the disclosure includes at least one first chip, at least one second chip, a plurality of fourth chips, a first redistribution layer, a second redistribution layer, a third redistribution layer, a first dielectric body, a second dielectric body, and a plurality of conductive members. The first chip is disposed between the first redistribution layer and the third redistribution layer. The conductive members are disposed between the first redistribution layer and the second redistribution layer, and the second redistribution layer is electrically connected to the first chip through the conductive members and the first redistribution layer. The second redistribution layer is disposed between the second chip and the plurality of fourth chips. At least two of the plurality of fourth chips are electrically connected to each other through the second redistribution layer and the second chip. The first dielectric body at least covers the first chip, the second chip, the first redistribution layer, the second redistribution layer, the third redistribution layer, and the conductive members. The second dielectric body at least covers the second redistribution layer.

A manufacturing method of a package structure in the disclosure includes the following. A chip stack is provided, which includes at least one first chip, a first redistribution layer, and at least one second chip. A first dielectric body is formed. A second redistribution layer is formed on the first dielectric body. A plurality of fourth chips are disposed on the second redistribution layer. A second dielectric body is formed. The first chip is disposed between the first redistribution layer and the third redistribution layer. A conductive member is disposed between the first redistribution layer and the second redistribution layer, and the second redistribution layer is electrically connected to the first chip through the conductive member and the first redistribution layer. The second redistribution layer is disposed between the second chip and the plurality of fourth chips. At least two of the plurality of fourth chips are electrically connected to each other through the second redistribution layer and the second chip. The first dielectric body at least covers the first chip, the second chip, the first redistribution layer, the second redistribution layer, the third redistribution layer, and the conductive member. The second dielectric body at least covers the second redistribution layer.

Based on the above, the package structure in the disclosure may have a smaller size. In addition, through the configuration of the corresponding devices/components (e.g., the chips, the redistribution layers, the dielectric bodies, and the conductive members), the package structure may have better quality or performance.

### BRIEF DESCRIPTION OF THE DRAWINGS

FIGS. 1A to 1K are schematic partial cross-sectional views of a partial manufacturing method of a package structure according to the first embodiment of the disclosure.

FIG. 1J is a schematic partial cross-sectional view of the package structure according to the first embodiment of the disclosure.

FIG. 1K is a schematic partial cross-sectional view of the package structure according to the first embodiment of the disclosure.

FIG. 1L is a schematic partial top view of the package structure according to the first embodiment of the present disclosure.

FIG. 2 is a schematic partial cross-sectional view of a package structure according to the second embodiment of the disclosure.

FIG. 3A is a schematic partial cross-sectional view of a partial manufacturing method of a package structure according to the third embodiment of the disclosure.

FIG. 3B is a schematic partial cross-sectional view of a package structure according to the third embodiment of the disclosure.

FIG. 4 is a schematic partial cross-sectional view of a package structure according to the fourth embodiment of the disclosure.

### DETAILED DESCRIPTION OF DISCLOSED EMBODIMENTS

Directional terms (e.g., up, down, top, bottom) used herein are used by reference only to the drawings and are not intended to imply absolute orientation. In addition, for clarity of description, some film layers or components may be omitted in the drawings.

Unless otherwise expressly stated, any method described herein is in no way intended to be construed as requiring that steps thereof be performed in a particular order.

The disclosure will be described more fully with reference to the drawings in this embodiment. However, the disclosure may also be embodied in various forms and should not be limited to the embodiments described herein. Thicknesses, sizes, or dimensions of layers or regions in the drawings may be enlarged for clarity. The same or similar reference numerals indicate the same or similar components, and will not be repeated one by one in the following paragraphs.

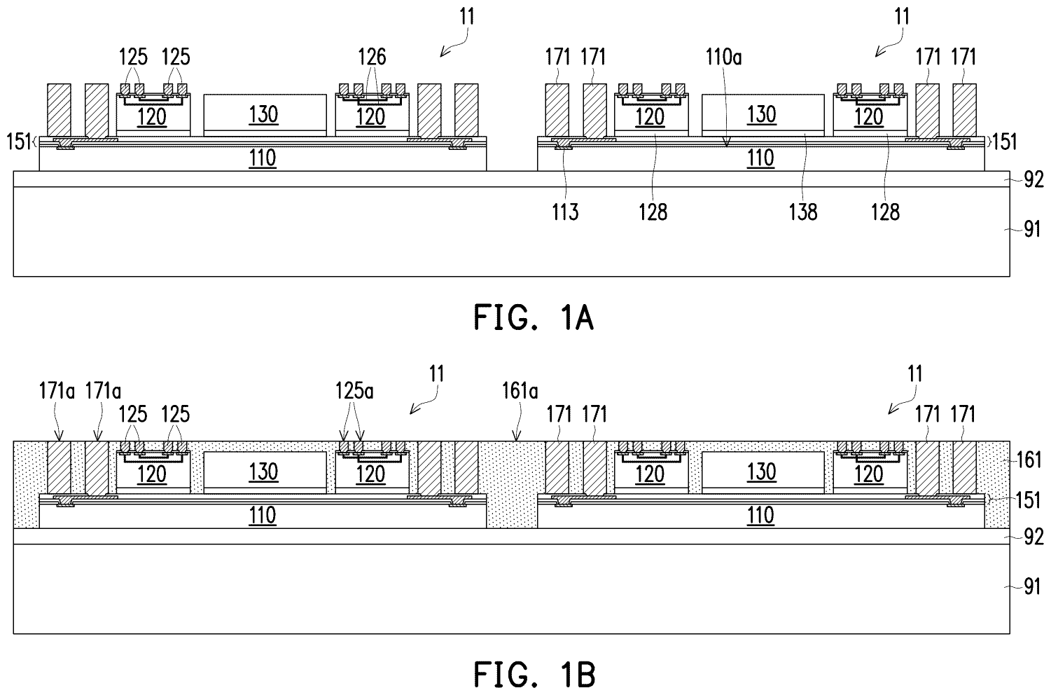

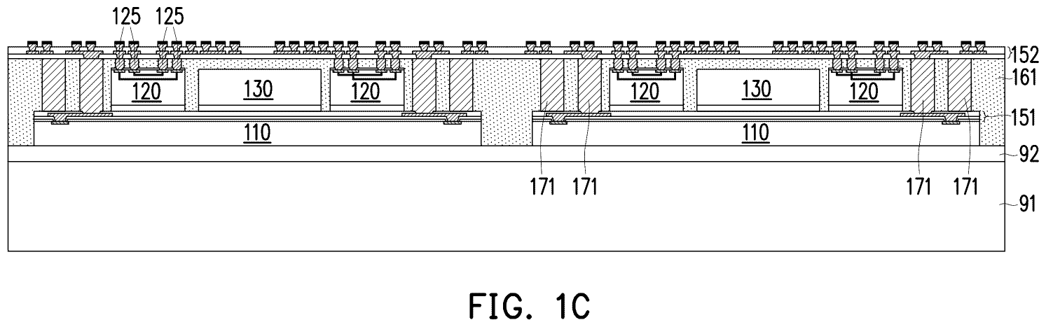

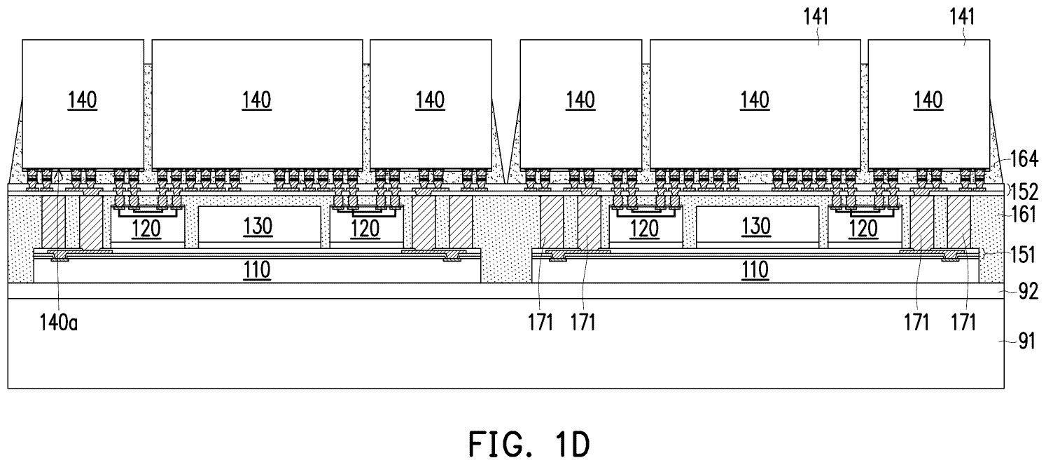

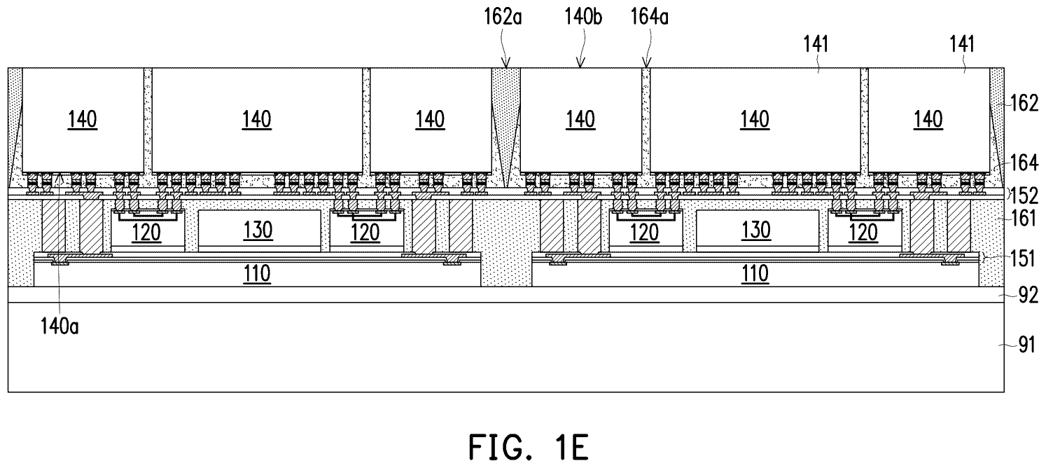

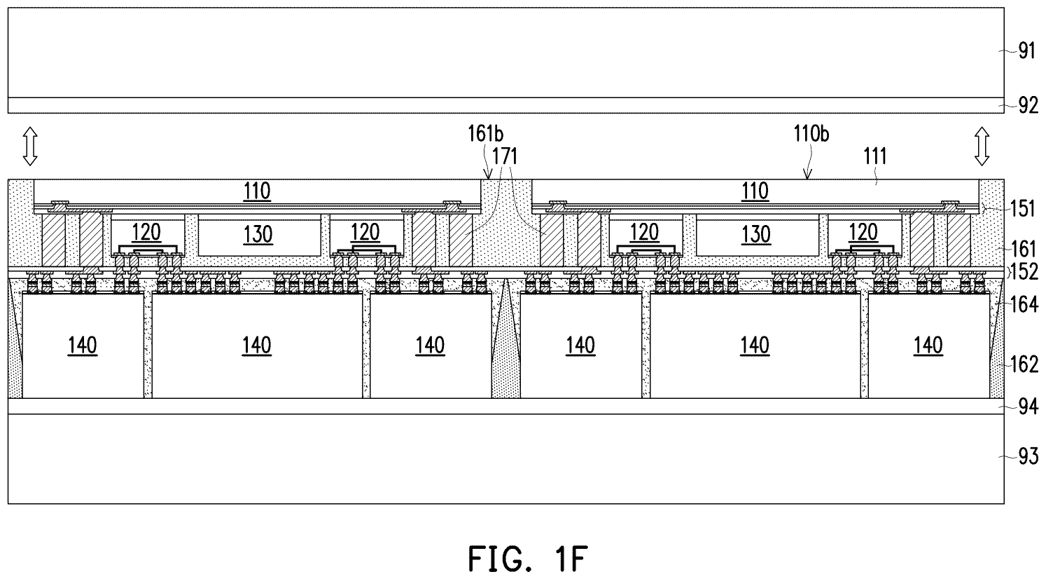

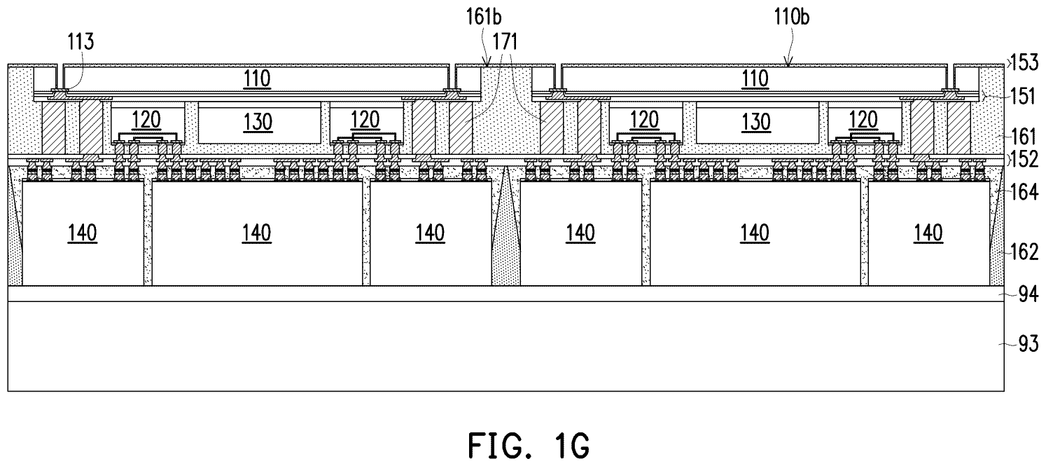

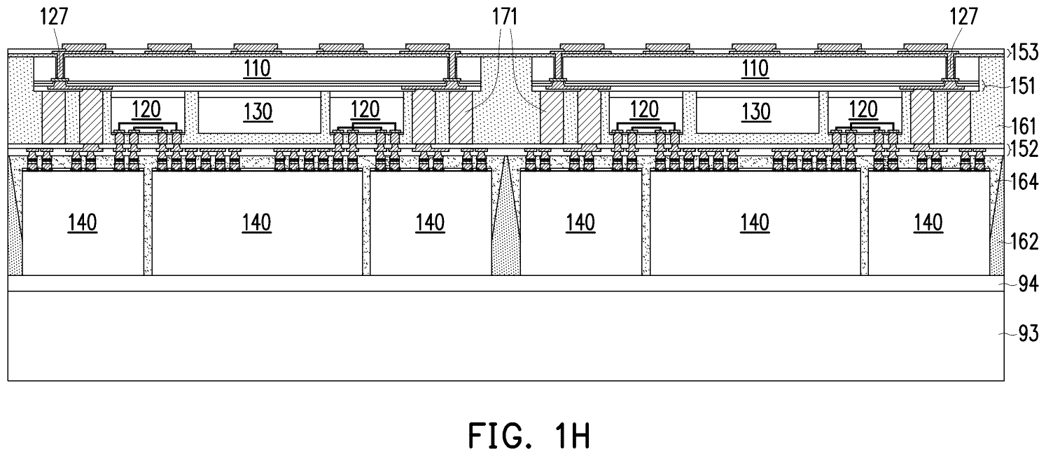

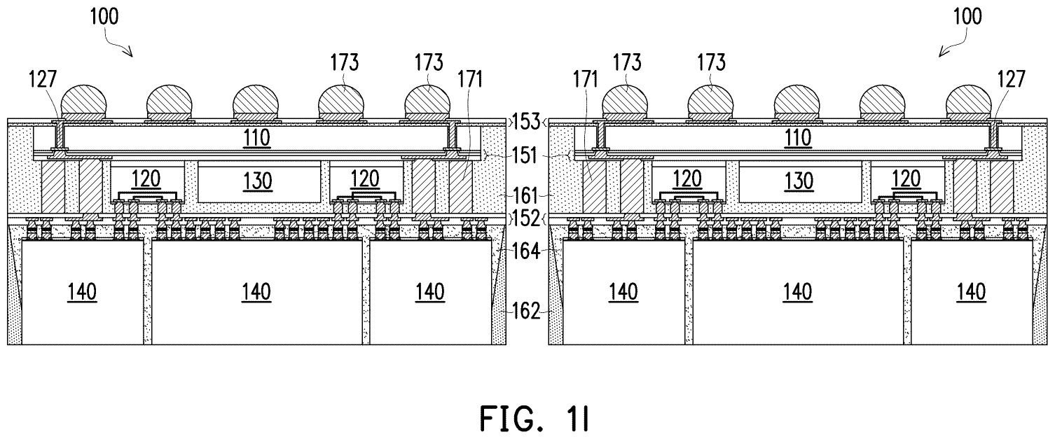

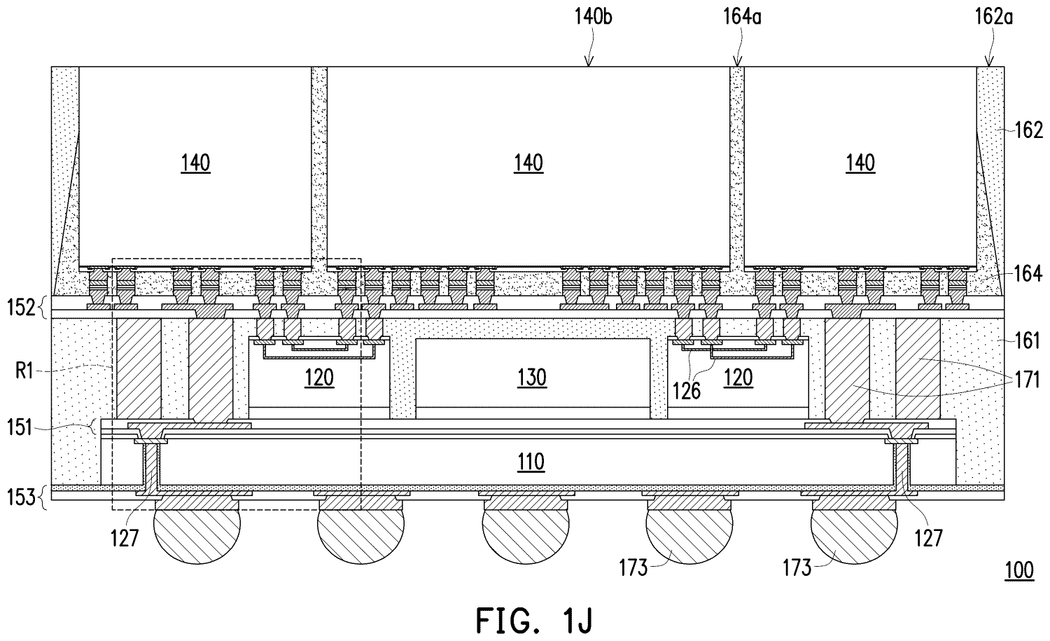

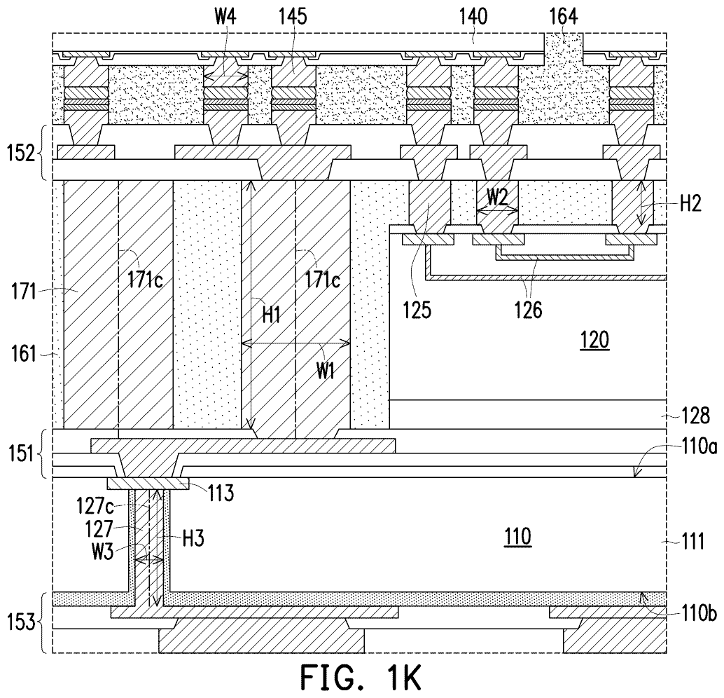

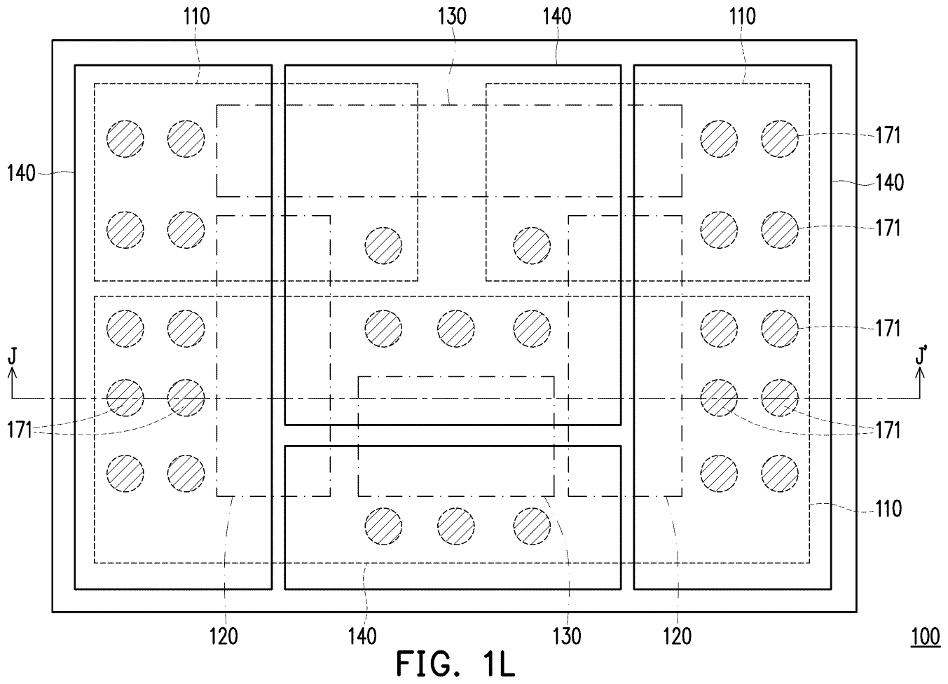

FIGS. 1A to 1K are schematic partial cross-sectional views of a partial manufacturing method of a package structure according to the first embodiment of the disclosure.

Referring to FIG. 1A, a first carrier 91 is provided. The first carrier 91 may be formed by glass, a wafer substrate, metal, or other suitable materials as long as the aforementioned materials may carry structures or components formed thereon in subsequent manufacturing processes. In an embodiment, the first carrier 91 may have a first release layer 92. The first release layer 92 may include a light to heat conversion (LTHC) adhesion layer, but the disclosure is not limited thereto.

Referring to FIG. 1A, a chip stack 11 is provided. It is worth noting that only two chip stacks 11 are illustrated exemplarily in FIG. 1A, but the disclosure does not limit the number and/or arrangement of the provided chip stacks 11. The chip stack 11 may include at least one first chip 110 and at least one second chip 120. The second chip 120 is stacked on the first chip 110. The first chip 110 and the second chip 120 may be heterogeneous chips.

In an embodiment, the first chip 110 may be an active chip. The active chip is a chip that includes an active device (e.g., a transistor). For example, the first chip 110 may be an active power delivery chip, and may at least perform voltage regulation, rectification, shunting, switching, frequency modulation, phase change, or other appropriate power regulation or power management on the power input thereto through the active device therein (or further including a corresponding passive device or appropriate wiring line).

In an embodiment, the first chip 110 may be a passive chip. The passive chip is a chip that does not include the active device (e.g., the transistor). For example, the first chip 110 may perform voltage reduction, rectification, shunting, or other appropriate power management on the power input thereto through the passive device (e.g., a resistor or a capacitor) or appropriate wiring line.

In an embodiment, one side of the second chip 120 may include a plurality of chip connecting members 125. The chip connecting member 125 may include, for example, a conductive pillar or a conductive bump, but the disclosure is not limited thereto. At least two of the chips connecting members 125 in the same second chip 120 may be electrically connected to each other through a corresponding wiring line 126 in the second chip 120. It is worth noting that in FIG. 1A or other similar drawings, the wiring line 126 in the second chip 120 is only schematically illustrated, and the aforementioned wiring line 126 may include interconnects in back end of line (BEOL), chip redistribution routing (e.g., a fan-in redistribution layer (fan-in RDL)), or a combination of the above. However, the disclosure is not limited thereto. In an embodiment, the second chip 120 may be referred as a bridge chip.

In an embodiment, the second chip 120 may be a passive chip.

In an embodiment, the chip stack 11 may further include at least one third chip 130. The third chip 130 is stacked on the first chip 110. The first chip 110, the second chip 120, and the third chip 130 may be heterogeneous chips.

In an embodiment, the third chip 130 may be a dummy chip. However, it is worth noting that “dummy” of the dummy chip herein may only mean that the chip does not actually participate in transmission of signals. However, the third chip 130, which is referred as the dummy chip, may still have structurally supporting, adjusting structural warpage during a manufacturing process, shielding (e.g., electromagnetic interference shielding (EMI Shielding)), performing heat transfer or other suitable purposes. For example, the third chip 130 that may be used for structurally supporting or adjusting structural warpage during a manufacturing process (but may also include other purposes) may be referred as a structure chip.

In an embodiment, the chip stack 11 may further include a corresponding first redistribution layer 151. The first redistribution layer 151 may include a corresponding wiring layer (not labeled, which may be a framed area including oblique lines of the first redistribution layer 151 as shown in FIG. 1A or a drawing similar thereof) and an insulation layer (not labeled, which may be a frame blank area of the first redistribution layer 151 as shown in FIG. 1A or a drawing similar thereof). The first redistribution layer 151 is disposed on an active surface 110a of the first chip 110, and a corresponding wiring line in the first redistribution layer 151 may be electrically connected to the first chip 110 (e.g., a pad 113 disposed on or corresponding to the active surface 110a). A layout design in the first redistribution layer 151 may be adjusted according to design requirements, and the disclosure is not limited thereto.

In addition, in order for the drawing to be concise and clear, the wiring layer and the insulation layer of the first redistribution layer 151 are not directly labeled in FIG. 1A or other similar drawings. However, in FIG. 1A or other similar drawings, the framed area with the oblique lines in the first redistribution layer 151 may be the corresponding wiring layer included therein.

In an embodiment, a portion of the first redistribution layer 151 may be disposed between the first chip 110 and the second chip 120, and/or the portion of the first redistribution layer 151 may be disposed between the first chip 110 and the third chip 130. For example, the second chip 120 or the third chip 130 may be attached to the portion of the first redistribution layer 151 through a corresponding adhesion layer (e.g., a die attach film (DAF)) 128 and 138. In an embodiment, the first redistribution layer 151 may be the fan-in RDL corresponding to the first chip 110.

In an embodiment, the chip stack 11 may further include a corresponding conductive member 171. The conductive member 171 may include a pre-formed conductive member. For example, the conductive member 171 may include a pre-formed conductive pillar, but the disclosure is not limited thereto. The conductive member 171 may be electrically connected to the first chip 110. For example, the conductive member 171 may be disposed on the first redistribution layer 151, and the conductive member 171 may be electrically connected to the first chip 110 through the corresponding wiring line in the first redistribution layer 151.

Referring to FIGS. 1A and 1B, a first dielectric body 161 covering the chip stack 11 is formed. The first dielectric body 161 may expose a portion of the chip stack 11. For example, the first dielectric body 161 may expose the chip connecting member 125 (if any) of the second chip 120 and/or the conductive member 171 (if any).

In an embodiment, the first dielectric body 161 is, for example, a molding compound. The molding compound may include, but is not limited to, epoxy. The first dielectric body 161 is formed of a polymer on the first carrier 91 by, for example, a molding process, a coating process, or other suitable methods. Then, the gelled or molten polymer is cured or semi-cured. Next, the portion of the chip stack 11 is exposed through an appropriate removal process.

In an embodiment, a first dielectric surface 161a of the first dielectric 161, a top surface 125a of the chip connecting member 125 (if any), and/or a top surface 171a of the conductive member 171 (if any) may be basically coplanar by chemical mechanical polishing (CMP), mechanical grinding, etching, or other suitable planarization processes.

In a manufacturing method not shown, the first dielectric body 161 may be formed by a photo imageable dielectric (PID) material. In addition, a portion of the photo imageable dielectric material may be removed through an appropriate manufacturing process to form an opening that exposes the portion of the first redistribution layer 151. Then, a conductive material is filled into the aforementioned opening to form a conductive member similar to the conductive member 171 and the corresponding first dielectric body 161.

Referring to FIGS. 1B to 1C, a second redistribution layer 152 is formed on the first dielectric body 161. The second redistribution layer 152 may include the corresponding wiring layer (not diagonal, which may be the framed area including the oblique lines of the second redistribution layer 152 as shown in FIG. 1C or a drawing similar thereof) and the insulation layer (not labeled, which may be a frame blank area of the second redistribution layer 152 as shown in FIG. 1C or a drawing similar thereof). A corresponding wiring line in the second redistribution layer 152 may be electrically connected to the first chip 110 and/or the second chip 120. For example, the corresponding wiring line in the second redistribution layer 152 may be electrically connected to the first chip 110 through the corresponding conductive member 171. For example, the corresponding wiring line in second redistribution layer 152 may be electrically connected to the corresponding chip connecting member. A layout design in the second redistribution layer 152 may be adjusted according to the design requirements, and the disclosure is not limited thereto.

In addition, in order for the drawing to be concise and clear, the wiring layer and the insulation layer of the second redistribution layer 152 are not directly labeled in FIG. 1C or other similar drawings. However, in FIG. 1C or other similar drawings, the framed area with the oblique lines in the second redistribution layer 152 may be the corresponding wiring layer included therein.

In an embodiment, a topmost wiring layer in the second redistribution layer 152 may include a bonding pad. In subsequent steps, the bonding pad may be adapted to be bonded to another electronic device.

In an embodiment, the second redistribution layer 152 may be referred as a fan-out RDL.

Referring to FIGS. 1C to 1D, a plurality of fourth chips 140 are disposed on the second redistribution layer 152. The fourth chip 140 may be electrically connected to the corresponding wiring line in the second redistribution layer 152 in an appropriate manner. For example, an active surface 140a of the fourth chip 140 may face the second redistribution layer 152, and the fourth chip 140 may electrically connect a chip connecting member 145 thereof (labeled in FIG. 1K) to the corresponding bonding pad in the second redistribution layer 152 through flip chip bonding.

Continuing to refer to FIG. 1D, after the fourth chips 140 are disposed on the second redistribution layer 152, a filling layer 164 may be formed between each of the fourth chips 140 and the second redistribution layer 152. The filling layer 164 is formed, for example, by capillary underfill (CUF) or other suitable filling colloids. For example, the filling colloid may be filled at least between the fourth chip 140 and the second redistribution layer 152, and the filling colloid may further cover a portion of a side wall of the fourth chip 140. Then, the corresponding filling layer 164 may be formed through appropriate curing methods.

In an embodiment not shown, it is not ruled out that other devices (e.g., an integrated passive device (IPD)) different from the fourth chip 140 are further disposed on the second redistribution layer 152. The aforementioned other devices may be electrically connected to the corresponding wiring line in second redistribution layer 152.

In the subsequent steps, the filling layer 164 may improve the bonding between the fourth chip 140 and the second redistribution layer 152.

Referring to FIGS. 1D to 1E, a second dielectric body 162 is formed, and the fourth chips 140 are thinned. The second dielectric body 162 may expose the fourth chips 140. It is worth noting that the disclosure does not limit an order between forming the second dielectric body 162 and thinning the fourth chips 140.

In an embodiment, a material and/or a formation method of the second dielectric body 162 may be the same or similar to that of the first dielectric body 161. For example, the polymer may be formed on the first carrier 91 through the molding process, the coating process, or other suitable methods. Then, the gelled or molten polymer is cured or semi-cured. Next, the cured or semi-cured polymer may expose the fourth chip 140 through the appropriate removal process. In addition, during the aforementioned removal process, the fourth chip 140 may be thinned by removing a portion of the fourth chip 140 (e.g., a silicon material 141 of the chip). Since a structure on the first carrier 91 as shown in FIG. 1D already has a considerable thickness, and the fourth chip 140 has been fixed on the second redistribution layer 152, the fourth chip 140 may be easily thinned to an appropriate thickness. In this way, an overall thickness of the package structure (e.g., a package structure 100 described later) may be reduced. In addition, for the sake of simplicity, the fourth chip 140 after thinning has no obvious impact on the use, so the fourth chip 140 before and after thinning is denoted by the same reference numeral.

In an embodiment, during a process of thinning the fourth chip 140, a portion of the filling layer 164 and/or a portion of the second dielectric body 162 may be removed.

In an embodiment, a material of the second dielectric body 162 is different from a material of the filling layer 164, and a contact position between the second dielectric body 162 and the filling layer 164 may have an interface formed due to the different materials.

In an embodiment, a third dielectric surface 162a of the second dielectric body 162, a back 140b of the fourth chip 140, and/or a top surface 164a of the filling layer 164 (if any) may be basically coplanar by chemical mechanical polishing, mechanical polishing, etching, or other suitable planarization processes.

Referring to FIGS. 1E to 1F, the structure on the first carrier 91 is transferred to a second carrier 93. A transfer method may be through a transfer process commonly used in a manufacturing process of an electronic product. For example, the second carrier 93 may be provided. Then, the structure (as shown in FIG. 1E) on the first carrier 91 is sandwiched between the first carrier 91 and the second carrier 93. Next, the first carrier 91, the second carrier 93, and the structure sandwiched therebetween are turned upside down. After that, a structure (as shown in FIG. 1F) on the second carrier 93 and the first carrier 91 are separated from each other.

In an embodiment, a material or size of the second carrier 93 may be the same as or similar to that of the first carrier 91. In an embodiment, the second carrier 93 may have a second release layer 94. In an embodiment, a material of the second release layer 94 may be the same as or similar to that of the first release layer 92.

In an embodiment, after the first carrier 91 is separated, the back 110b of the first chip 110 may be exposed.

In an embodiment, if necessary, the appropriate removal process may be performed to remove a portion of the first chip 110 (e.g., a silicon material 111 of the chip), so that the first chip 110 is thinned. Since the structure on the second carrier 93 as shown in FIG. 1F already has a considerable thickness, and the first chip 110 has been well fixed, the first chip 110 may be easily thinned to an appropriate thickness. In this way, the overall thickness of the package structure (e.g., the package structure 100 described later) may be reduce. In addition, for the sake of simplicity, the first chip 110 after thinning has no obvious impact on the use, so the first chip 110 before and after thinning is denoted by the same reference numeral.

In an embodiment, during a process of thinning the first chip 110, a portion of the first dielectric body 161 may be removed.

In one embodiment, a second dielectric surface 161b of the first dielectric body 161 and the back 110b of the first chip 110 may be basically coplanar by chemical mechanical polishing, mechanical polishing, etching, or other suitable planarization processes.

Referring to FIGS. 1F to 1H, a through silicon via (TSV) 127 and a third redistribution layer 153 are formed. A layout design in third redistribution layer 153 may be adjusted according to the design requirements, and the disclosure is not limited thereto.

Referring to FIGS. 1F to 1G, an opening exposing the pad 113 may be formed from the back 110b of the first chip 110 by etching or other suitable methods. After the opening is formed, a corresponding insulation layer (not labeled, which may be a framed area including dense dots of the third redistribution layer 153 as shown in FIGS. 1G and/or 1H or a drawing similar thereof) may be formed by deposition, etching, and/or other suitable methods. The insulation layer may cover the back 110b of the silicon material 111 and a side wall of the opening, and the insulation layer may expose the pad 113.

Referring to FIGS. 1G to 1H, after the insulation layer exposing the pad 113 is formed, a corresponding conductive layer (not labeled, which be a framed area including oblique lines of the third redistribution layer 153 as shown in FIG. 1H or a drawing similar thereof) may be formed by deposition, plating, etching, and/or other suitable methods. The conductive layer includes, for example, a corresponding seed layer and a corresponding plating layer, but the disclosure is not limited thereto. A portion of the conductive layer disposed in the opening and the corresponding insulation layer may be referred to as the through silicon via 127. A portion of the conductive layer disposed on the back 110b of the silicon material 111 may be referred to as a wiring layer. That is to say, a portion of the through silicon via 127 that may be conductive and a portion of the wiring layer that may be conductive may be the same film layer. Then, the corresponding insulation layer (not labeled, which may be a frame blank area of the third redistribution layer 153 as shown in FIG. 1H or a drawing similar thereof) and the wiring layer (not labeled, which may be the framed area including the oblique lines of the third redistribution layer 153 as shown in FIG. 1H or a drawing similar thereof) may be further formed on the aforementioned wiring layer by common semiconductor processes (e.g., film lamination, coating, deposition, plating, etching, and/or other suitable methods). The wiring layer and the insulation layer disposed on the back 110b of the silicon material 111 may form the third redistribution layer 153. In addition, for simplicity, the first chip 110 with the through silicon via 127 is still denoted by the same reference numeral.

In an embodiment, the third redistribution layer 153 may be a fan-out RDL corresponding to the first chip 110.

In an embodiment, a topmost wiring layer in the third redistribution layer 153 may include the bonding pad. In the subsequent steps, the bonding pad may be adapted to be bonded to another electronic device.

In addition, in order for the drawing to be concise and clear, the wiring layer and the insulation layer of the third redistribution layer 153 are not directly labeled in FIG. 1H or other similar drawings. However, in FIG. 1H or other similar drawings, the framed area with the oblique lines in the third redistribution layer 153 may be the corresponding wiring layer included therein.

Referring to FIGS. 1H to 1I, the second carrier 93 and the structure thereon are separated from each other. For example, bonding force of the second release layer 94 (or any) may be reduced by light, heat, or other suitable methods, and the second carrier 93 and the structure thereon may be separated from each other by applying force.

Referring to FIGS. 1H to 1I, a plurality of conductive terminals 173 may be formed on the wiring layer of the third redistribution layer 153. The conductive terminal 173 may be electrically connected to the first chip 110 through a corresponding wiring line in the third redistribution layer 153. In addition, for the sake of clarity, not all the conductive terminals 173 are labeled one by one in FIG. 1I or other similar drawings.

The conductive terminal 173 may be a conductive pillar, a solder ball, a conductive bump, or a conductive terminal having other forms or shapes. The conductive terminal 173 may be formed through electroplating, deposition, ball placement, reflow, and/or other suitable processes.

Continuing to refer to FIG. 1I, in this embodiment, a plurality of package structures 100 may be formed through a singulation process. For example, the singulation process may include a dicing process/cutting process to cut through the corresponding redistribution layer (e.g., the second redistribution layer 152 and/or the third redistribution layer 153) and/or the corresponding dielectric body (e.g., the first dielectric body 161 and/or the second dielectric body 162).

It is worth noting that after the singulation process is performed, similar reference numerals will be used for the devices after singulation. For example, the first chip 110 (shown in FIG. 1H) may be the first chip 110 (shown in FIG. 11) after singulation. The first dielectric body 161 (shown in FIG. 1H) may be the first dielectric 161 body (shown in FIG. 11) after singulation. The first redistribution layer 151 (shown in FIG. 1H) may be the first redistribution layer 151 (shown in FIG. 11) after singulation. The conductive terminals 173 (if these conductive terminals 173 were already present before the singulation process) may be the conductive terminals 173 (as shown in FIG. 11) after singulation, and so on. Other devices after singulation will follow the aforementioned rule of the same reference numerals, which will not be repeated or specifically illustrated in the following.

It is worth noting that the disclosure does not limit an order of removing the second carrier 93, disposing the conductive terminals 173 (if any), and performing singulation process (if necessary).

In an embodiment, after the aforementioned singulation process is completed, a side wall of the second redistribution layer 152, a side wall of the third redistribution layer 153, and a side walls of the dielectric body (e.g., the first dielectric body 161 and/or the second dielectric body 162) may be flush or aligned with each other.

After the above steps, fabrication of the package structure 100 in this embodiment may be substantially completed.

FIG. 1J is a schematic partial cross-sectional view of the package structure according to the first embodiment of the disclosure. FIG. 1K is a schematic partial cross-sectional view of the package structure according to the first embodiment of the disclosure. FIG. 1L is a schematic partial top view of the package structure according to the first embodiment of the present disclosure. For example, FIG. 1K may be an enlarged view corresponding to a region R1 in FIG. 1J. For example, FIG. 1J may be a schematic cross-sectional view corresponding to a J-J′ line in FIG. 1L. It is also worth noting that the package structure in FIGS. 1J to 1L may be manufactured by the manufacturing method shown in FIGS. 1A to 1I or correspondingly described, but the disclosure is not limited thereto.

Referring to FIGS. 1J to 1L, the package structure 100 includes at least one first chip 110, at least one second chip 120, the fourth chips 140, the first redistribution layer 151, the second redistribution layer 152, the third redistribution layer 153, the first dielectric body 161, the second dielectric body 162, and the conductive members 171. The first chip 110 is disposed between the first redistribution layer 151 and the third redistribution layer 153. The conductive member 171 is disposed between the first redistribution layer 151 and the second redistribution layer 152, and the corresponding wiring line in the second redistribution layer 152 is electrically connected to the first chip 110 through the corresponding conductive member 171 and the corresponding wiring line in the first redistribution layer 151. The second redistribution layer 152 is disposed between the second chip 120 and the fourth chip 140. At least two of the fourth chips 140 are electrically connected to the corresponding second chip 120 through the corresponding wiring line in the second redistribution layer 152. The first dielectric body 161 at least covers the first chip 110, the second chip 120, the first redistribution layer 151, the second redistribution layer 152, the third redistribution layer 153, and the conductive member 171. The second dielectric body 162 covers at least the second redistribution layer 152.

In an embodiment, the first dielectric body 161 and the second dielectric body 162 are physically separated from each other by at least the second redistribution layer 152.

In an embodiment, the package structure 100 further includes at least one third chip 130. The third chip 130 is disposed between the first redistribution layer 151 and the second redistribution layer 152, and/or the second redistribution layer 152 is disposed between the third chip 130 and the fourth chip 140.

In an embodiment, the package structure 100 further includes the filling layer 164. The filling layer 164 is at least disposed between the fourth chip 140 and the second redistribution layer 152, and/or the filling layer 164 laterally covers the portion of the fourth chip 140. The second dielectric body 162 may further cover the portion of the filling layer 164. In an embodiment, the second dielectric body 162 may expose a portion of another portion of the filling layer 164 that is not covered by the second dielectric body 162.

In an embodiment, the first chip 110 may have the through silicon via 127. The corresponding wiring line in the first redistribution layer 151 may be electrically connected to the corresponding wiring line in the third redistribution layer 153 through the corresponding through silicon via 127 in the first chip 110.

In an embodiment, in a direction parallel to a thickness of the package structure 100, the conductive member 171 has a first height H1, the chip connecting member 125 of the second chip 120 has a second height H2, and the through silicon via 127 of the first chip 110 has a third height

H3. The first height H1 is greater than or substantially equal to the third height H3, and/or the third height H3 is greater than or substantially equal to the second height H2. In an embodiment, the height (e.g., corresponding to the first height H1) of any of the conductive members 171 is greater than or substantially equal to the height (e.g., corresponding to the third height H3) of any of the through silicon vias 127 in the first chip 110, and/or the height (e.g., corresponding to third height H3) of any of the through silicon vias 127 in any of the first chips 110 is greater than or substantially equal to the height (e.g., corresponding to second height H2) of any of the chip connecting members 125 in any of the second chips 120.

In an embodiment, in a direction perpendicular to the thickness of the package structure 100, the conductive member 171 has a first width W1, the chip connecting member 125 of the second chip 120 has a second width W2, the chip connecting member 145 of the fourth chip 140 has a fourth width W4, and a conductive area of the through silicon via 127 of the first chip 110 has a third width W3. The first width W1 is greater than or substantially equal to the second width W2, and/or the second width W2 is greater than or substantially equal to the third width W3. The first width W1 is greater than or substantially equal to the fourth width W4, and/or the fourth width W4 is greater than or substantially equal to the third width W3.

In an embodiment, the second width W2 may be basically the same as or similar to the fourth width W4 (e.g., a ratio is between 95% and 105%), but the disclosure is not limited thereto.

In an embodiment, the width (e.g., corresponding to the first width W1) of any of the conductive members 171 is greater than or substantially equal to the width (e.g., corresponding to the second width W2) of any of the chip connecting members 125 in any of the second chips 120, the width (e.g., corresponding to the first width W1) of any of the conductive members 171 is greater than or substantially equal to the width (e.g., corresponding to the fourth width W4) of any of the chip connecting members 145 in any of the fourth chips 140, and/or the width (e.g., corresponding to the second width W2) of any of the chip connecting members 125 in any of the second chips 120 is greater than or substantially equal to the width (e.g., corresponding to the third width W3) of any of the through silicon vias 127 in any of the first chips 110.

In an embodiment, as shown in FIG. 1K, a center line 171c of the conductive member 171 is not aligned with a center line 127c of the through silicon via 127. In an embodiment, the center line 171c of any of the conductive members 171 is not aligned with the center line 127c of any of the through silicon vias 127 in any of the first chips 110. In this way, during a manufacturing process of the package structure 100 and/or for an overall structure of the package structure 100, a possibility of defects caused by stress effects (e.g., uneven stress) may be reduced, and a manufacturing yield and/or quality of the package structure 100 may be improved.

In an embodiment, all the fourth chips 140 have a corresponding fourth projection area on a plane (e.g., each fourth chip 140 has a corresponding single projected area, and the fourth projected area is the sum of the aforementioned single projected areas). All the first chip(s) 110 has/have a corresponding first projection area on the plane (e.g., there is only one first chip 110, and the first projected area is the single projected area of the single first chip 110; either or, there are a plurality of first chips 110, each first chip 110 has a corresponding single projected area, and the first projected area is the sum of the aforementioned single projected areas). All the second chip(s) 120 has/have a corresponding second projection area on the plane (e.g., there is only one second chip 120, and the second projected area is the single projected area of the single second chip 120; either or, there are a plurality of second chips 120, each second chip 120 has a corresponding single projected area, and the second projected area is the sum of the aforementioned single projected areas). A thickness direction of the package structure 100 is perpendicular to the plane (e.g., a plane shown in FIG. 1L). The fourth projection area is greater than or substantially equal to the first projection area, and/or the first projection area is greater than or substantially equal to the second projection area.

In an embodiment, all the third chips 130 have a corresponding third projection area on the plane (e.g., there is only one third chip 130, and the third projected area is the single projected area of the single third chip 130; either or, there are a plurality of third chips 130, each third chip 130 has a corresponding single projected area, and the third projected area is the sum of the aforementioned single projected areas), and the first projection area is greater than or substantially equal to a sum of the second projection area and the third projection area.

In an embodiment, the package structure 100 has a corresponding total projection area on the plane. In addition, the first projection area accounts for approximately 50% to 90% of the total projection area, the second projection area accounts for approximately 1% to 10% of the total projection area, the fourth projection area accounts for approximately 75% to 95% of the total projection area, and/or the sum of the second projection area and the third projection area accounts for approximately 5% to 30% of the total projection area.

In an embodiment, during the manufacturing process of the package structure 100, the first chip 110 and/or the fourth chip 140 may be moderately thinned. In addition, before or during thinning of the first chip 110 and/or the fourth chip 140, the first chip 110 and/or the fourth chip 140 have been well fixed, and/or the corresponding structures on the carrier already have a thicker thickness. In this way, the first chip 110 and/or the fourth chip 140 may be easily thinned to the appropriate thickness, and the overall thickness of the package structure 100 may be reduced.

In an embodiment, since the conductive member 171 is disposed on the active surface 110a of the first chip 110, it may be electrically connected to the first chip 110 through the first redistribution layer 151 disposed on the active surface 110a. In this way, disposing the conductive member 171 on the first chip 110 may increase the configuration number and/or density of the conductive members 171 under an aspect ratio limit, so as to improve the manufacturing yield of the package structure 100 and/or enable the package structure 100 to have good quality.

In an embodiment where the first chip 110 is a power supply chip, one of the conductive members 171 may be electrically connected to the through silicon vias in the first chip 110 through the corresponding wiring lines in the first redistribution layer 151, and the aforementioned conductive member 171 may serve as a power supply source of the corresponding fourth chip 140. In this way, when the package structure 100 is operating, good power transmission quality may be achieved.

In an embodiment, the number of first chips 110 may be multiple, and the first chips 110 may be the same or similar power supply chips. For example, different first chips 110 may be electrically connected to the corresponding power supply source (e.g., the power supply source with different voltages or currents) through corresponding conductive terminal. In this way, when the package structure 100 is operating, the good power transmission quality may be achieved.

In an embodiment, the number of fourth chips 140 may be multiple. In an embodiment, the fourth chips 140 may be dies, chiplets, packaged chips, stacked chip packages, or application-specific integrated circuits (ASIC) with the same or different functions, but the disclosure is not limited thereto. For example, one of the fourth chips 140 may be a dynamic random access memory (DRAM) chip, a static random access memory (SRAM) chip, or a high bandwidth memory (HBM) chip, or other similar memory chips, but the disclosure is not limited thereto. For example, one of the fourth chips 140 may be an application-specific integrated circuit (ASIC) chip, an application processor (AP), a system on chip (SoC), a network-on-chip (NoC), or other similar high performance computing (HPC) chips, but the disclosure is not limited thereto. In an embodiment, two of the fourth chips 140 may be heterogeneous chips or homogenous chips.

In an embodiment, the first chip 110 and the fourth chip 140 may be disposed on two opposite sides of the package structure 100 respectively. Taking FIG. 1J as an example, the first chip 110 is disposed on a lower side of the package structure 100, and the fourth chip 140 is disposed on an upper side of the package structure 100. In this way, when the package structure 100 is operating, generated heat sources may be dispersed, so as to improve stability of the package structure 100 during operation and/or improve corresponding heat dissipation efficiency.

In an embodiment, signals between different fourth chips 140 are transmitted through the corresponding wiring line in the corresponding second chip 120. In this way, corresponding signal transmission quality and/or signal transmission efficiency may be improved.

In an embodiment, in the thickness direction of the package structure 100, all the chips between the first chip 110 and the fourth chip 140 (e.g., the second chip 120 and the third chip 130) are not the active chips. For example, the second chip 120 is the bridge chip for signal transmission, and the third chip 130 (if any) is the dummy chip. That is to say, when the package structure 100 is operating, the second chip 120 and/or the third chip 130 are hardly regarded as heat sources, but the silicon material forming the second chip 120 and/or the third chip 130 may still be a good heat conductor. In this way, when the package structure 100 is operating, the corresponding heat dissipation efficiency may be improved, and the stability of the package structure 100 during operation may be improved.

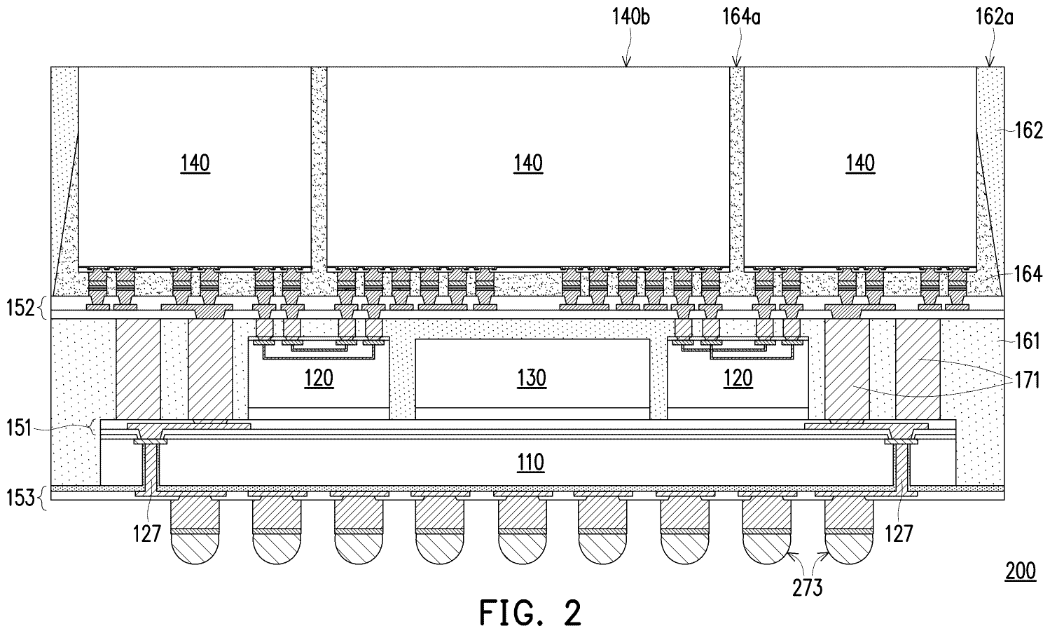

FIG. 2 is a schematic partial cross-sectional view of a package structure according to the second embodiment of the disclosure. A package structure 200 and/or a manufacturing method thereof in the second embodiment are similar to the package structure 100 and/or the manufacturing method thereof in the first embodiment. Similar components or regions thereof are denoted by the same reference numerals and have similar functions, materials, or formation method, and descriptions thereof are omitted.

Referring to FIG. 2, the package structure 200 includes the at least one first chip 110, the at least one second chip 120, the fourth chips 140, the first redistribution layer 151, the second redistribution layer 152, the third redistribution layer 153, the first dielectric body 161, the second dielectric body 162, and the conductive members 171. One of differences between the package structure 200 in this embodiment and the package structure 100 in the first embodiment is that a conductive terminal 273 may include an electroplated copper pillar bump. In this way, the conductive terminals 273 may have a smaller pitch therebetween, and the configuration number and/or density of conductive terminals 273 may be increased.

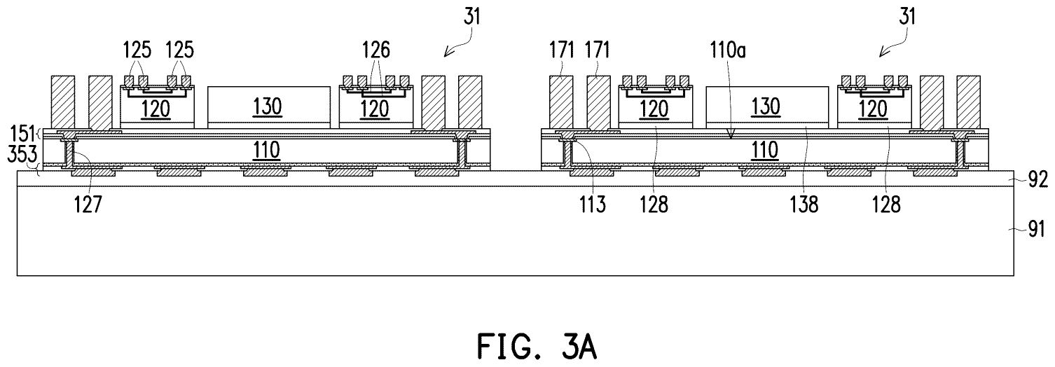

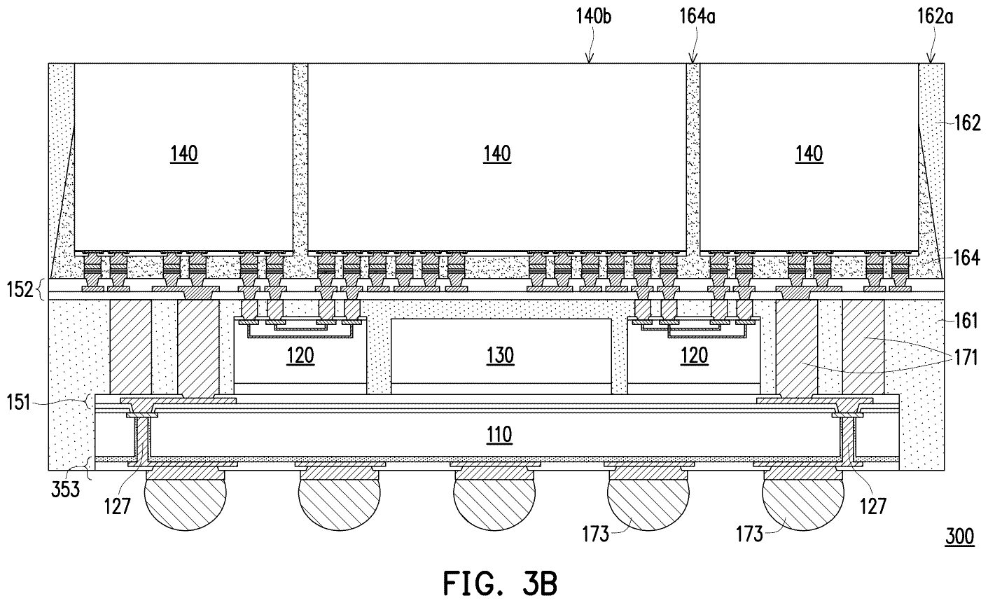

FIG. 3A is a schematic partial cross-sectional view of a partial manufacturing method of a package structure according to the third embodiment of the disclosure. A manufacturing method of a package structure 300 in the third embodiment is similar to the manufacturing method of the package structure 100 in the first embodiment. Similar components or regions thereof are denoted by the same reference numerals and have similar functions, materials, or formation method, and descriptions thereof are omitted.

Referring to FIG. 3A, similar to the steps shown in FIG. 1A, a chip stack 31 is provided. The chip stack 31 may include the at least one first chip 110 and the at least one second chip 120. The first chip 110 in the chip stack 31 is similar to the first chip 110 in the aforementioned chip stack 11. A difference thereof is that the first chip 110 in the chip stack 31 already has the corresponding through silicon via 127, and the first chip 110 has a corresponding third redistribution layer 353 on the back (bottom in FIG. 3A).

In an embodiment, the through silicon via 127 of the first chip 110 and/or the third redistribution layer 353 disposed thereon may be formed together in a corresponding wafer process thereof. Then, after a corresponding wafer dicing process is performed on a corresponding wafer, the first chip 110 with the through silicon via 127 and/or the third redistribution layer 353 disposed thereon may be formed.

Next, fabrication of the package structure 300 in this embodiment may be completed through the same or similar steps as shown in FIGS. 1A to 1I.

It is worth noting that although the first chip 110 in the chip stack 31 already has the corresponding through silicon via 127, the disclosure does not rule out a possibility of forming additional through silicon vias or other redistribution layers similar to the aforementioned third redistribution layer 153.

FIG. 3B is a schematic partial cross-sectional view of a package structure according to the third embodiment of the disclosure. It is worth noting that the package structure 300 in FIG. 3B may be manufactured by the manufacturing methods as shown in FIG. 3A or FIGS. 1A to 1I or correspondingly described, but the disclosure is not limited thereto. The package structure 300 and/or the manufacturing method thereof in the third embodiment are similar to the package structure 100 and/or the manufacturing method thereof in the first embodiment. Similar components or regions thereof are denoted by the same reference numerals and have similar functions, materials, or formation method, and descriptions thereof are omitted.

Referring to FIG. 3B, the package structure 300 includes the at least one first chip 110, the at least one second chip 120, the fourth chips 140, the first redistribution layer 151, the second redistribution layer 152, the third redistribution layer 353, the first dielectric body 161, the second dielectric body 162, and the conductive members 171. One of differences between the package structure 300 in this embodiment and the package structure 100 in the first embodiment is that the third redistribution layer 353 may be embedded in the first dielectric body 161.

In an embodiment, the third redistribution layer 353 may be a fan-in RDL corresponding to the first chip 110.

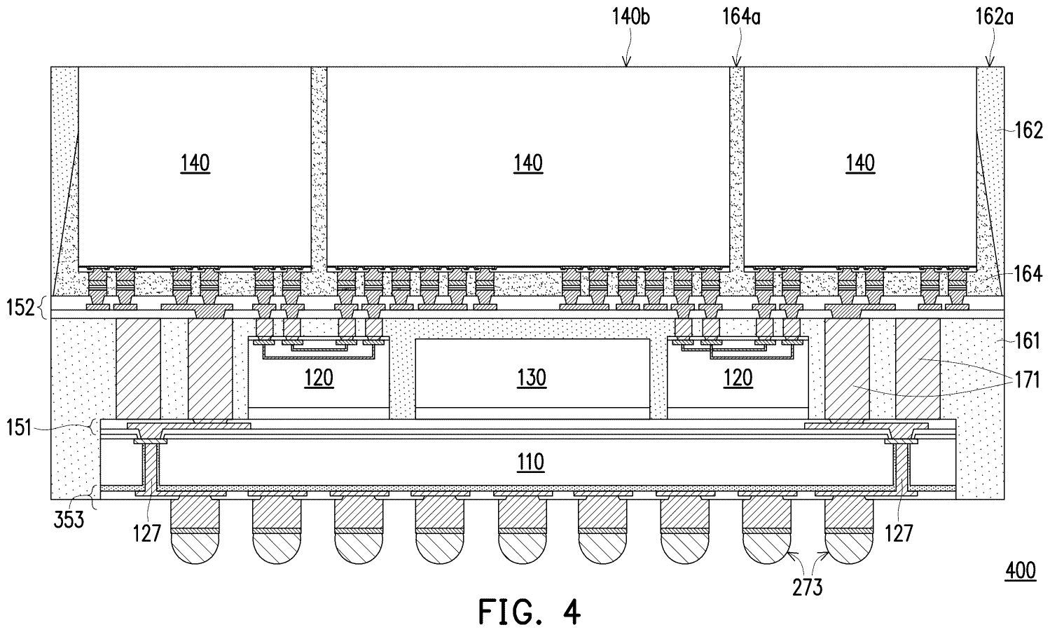

FIG. 4 is a schematic partial cross-sectional view of a package structure according to the fourth embodiment of the disclosure. A package structure 400 and/or a manufacturing method thereof in the fourth embodiment is similar to the package structure 300 and/or the manufacturing method thereof in the third embodiment. Similar components or regions thereof are denoted by the same reference numerals and have similar functions, materials, or formation method, and descriptions thereof are omitted.

Referring to FIG. 4, the package structure 400 includes the at least one first chip 110, the at least one second chip 120, the fourth chips 140, the first redistribution layer 151, the second redistribution layer 152, the third redistribution layer 353, the first dielectric body 161, the second dielectric body 162, and the conductive members 171. One of differences between the package structure 400 in this embodiment and the package structure 300 in the third embodiment is that the conductive terminal 273 may include the electroplated copper pillar bump. In this way, the conductive terminals 273 may have the smaller pitch therebetween, and the number or configuration density of conductive terminals 273 may be increased.

Based on the above, the package structure in the disclosure may have a smaller size. In addition, through the configuration of the corresponding devices/components (e.g., the chips, the redistribution layers, the dielectric bodies, and the conductive members), the package structure may have better quality or performance.

What is claimed is:

1. A package structure comprising at least one first chip, at least one second chip, a plurality of fourth chips, a first redistribution layer, a second redistribution layer, a third redistribution layer, a first dielectric body, a second dielectric body, and a plurality of conductive members, wherein
the first chip is disposed between the first redistribution layer and the third redistribution layer;
the plurality of conductive members are disposed between the first redistribution layer and the second redistribution layer, and the second redistribution layer is electrically connected to the first chip through at least one of the plurality of conductive members and the first redistribution layer;
the second redistribution layer is disposed between the second chip and the plurality of fourth chips;
at least two of the plurality of fourth chips are electrically connected to each other through the second redistribution layer and the second chip;
the first dielectric body at least covers the first chip, the second chip, the first redistribution layer, the second redistribution layer, the third redistribution layer, and the plurality of conductive members; and
the second dielectric body at least covers the second redistribution layer.

2. The package structure according to claim 1, wherein the first dielectric body and the second dielectric body are physically separated from each other through at least the second redistribution layer.

3. The package structure according to claim 1, wherein the package structure further comprises at least one third chip, wherein
the third chip is disposed between the first redistribution layer and the second redistribution layer; and/or
the second redistribution layer is disposed between the third chip and the plurality of fourth chips.

4. The package structure according to claim 3, wherein the third chip is a dummy chip.

5. The package structure according to claim 1, wherein the package structure further comprises a filling layer, wherein
the filling layer is at least disposed between the second redistribution layer and the plurality of fourth chips; and/or
the filling layer laterally covers a portion of the plurality of fourth chips.

6. The package structure according to claim 5, wherein the second dielectric body exposes a portion of the filling layer.

7. The package structure according to claim 1, wherein the first chip has a through silicon via, and the first redistribution layer is electrically connected to the third redistribution layer through the through silicon via of the first chip.

8. The package structure according to claim 1, wherein at least one of the plurality of conductive members has a first height, a chip connecting member of the second chip has a second height, and a through silicon via of the first chip has a third height, wherein
the first height is greater than or substantially equal to the third height; and/or
the third height is greater than or substantially equal to the second height.

9. The package structure according to claim 1, wherein in a direction perpendicular to a thickness of the package structure, at least one of the plurality of conductive members has a first width, a chip connecting member of the second chip has a second width, and a through silicon via of the first chip has a third width, wherein
the first width is greater than or substantially equal to the second width; and/or
the second width is greater than or substantially equal to the third width.

10. The package structure according to claim 1, wherein the first chip has a through silicon via, and a center line of any one of the plurality of conductive members is not aligned with a center line of the through silicon via.

11. The package structure according to claim 1, wherein a thickness direction of the package structure is perpendicular to a plane, all the plurality of fourth chips have a corresponding fourth projection area on the plane, all the first chips have a corresponding first projection area on the plane, and all the second chips has a corresponding second projection area on the plane, wherein
the fourth projection area is greater than or substantially equal to the first projection area; and/or
the first projection area is greater than or substantially equal to the second projection area.

12. The package structure according to claim 11, wherein the package structure further comprises at least one third chip, wherein
the third chip is disposed between the first redistribution layer and the second redistribution layer, and/or the second redistribution layer is disposed between the third chip and the plurality of fourth chips; and
all the third chips have a corresponding third projection area on the plane, and the first projection area is greater than or substantially equal to a sum of the second projection area and the third projection area.

13. A manufacturing method of a package structure, comprising:
providing a chip stack comprising at least one first chip, a first redistribution layer, and at least one second chip;
forming a first dielectric body;
forming a second redistribution layer on the first dielectric body;
disposing a plurality of fourth chips on the second redistribution layer;
forming a second dielectric body, wherein
the first chip is disposed between the first redistribution layer and the third redistribution layer;
a conductive member is disposed between the first redistribution layer and the second redistribution layer, and the second redistribution layer is electrically connected to the first chip through the conductive member and the first redistribution layer;
the second redistribution layer is disposed between the second chip and the plurality of fourth chips;
at least two of the plurality of fourth chips are electrically connected to each other through the second redistribution layer and the second chip;
the first dielectric body at least covers the first chip, the second chip, the first redistribution layer, the second redistribution layer, the third redistribution layer, and the conductive member; and
the second dielectric body at least covers the second redistribution layer.

14. The manufacturing method of the package structure according to claim 13, wherein the chip stack further comprises a plurality of the conductive members.

15. The manufacturing method of the package structure according to claim 13, further comprising:
after forming the second dielectric body, forming the third redistribution layer.

16. The manufacturing method of the package structure according to claim 13, further comprising: thinning the plurality of fourth chips.

17. The manufacturing method of the package structure according to claim 13, further comprising: thinning the first chip.
